(19) United States
(12) Patent Application Publication
(10) Pub. No.: US 2007/0162799 A1
(43) Pub. Date: Jul. 12, 2007

(54) Burn-in test signal generating circuit and burn-in testing method

(76) Inventor: Shinya Kamada, Osaka (JP)

Correspondence Address: MCDERMOTT WILL & EMERY LLP, 600 13TH STREET, N.W., WASHINGTON, DC, 20005-3096, US

(21) Appl. No.: 11/638,694

(22) Filed: Dec. 14, 2006

(30) Foreign Application Priority Data
Dec. 14, 2005 (JP) JP 2005-360146

(51) Int. Cl. G01R 31/28

(52) U.S. Cl. 714/724

(57) ABSTRACT

A burn-in test signal path is provided in parallel with an ordinary signal path with respect to an analog circuit. A signal waveform converting circuit for converting a burn-in test signal of a digital waveform into a burn-in test signal of an analog waveform is provided in the burn-in test signal path. The ordinary signal path is controlled to switch over to the burn-in test signal path in the burn-in test of the analog circuit.

### BACKGROUND OF THE INVENTION

1. Field of the Invention

The present invention relates to a burn-in test signal generating circuit and a burn-in testing method, more specifically, to a burn-in test signal generating circuit for generating a burn-in test signal applied to an analog circuit in a semiconductor device equipped with a combination of digital and analog circuits in one chip, such as a system LSI, and a burn-in testing method.

2. Description of the Related Art

The burn-in test is one of the screening methods for removing a failure (initial defect) of a semiconductor device, wherein an acceleration stress (burn-in voltage) of a higher voltage than that in operation conditions of the semiconductor device is applied so that the defective products are removed in a short period of time by accelerating a failure generation. The conditions and voltage application time of the burn-in voltage are different depending on technical standards, characteristic of a production process, guaranteed quality and the like of the semiconductor device.

The analog circuit in the system LSI with a mixed mounting of the digital and analog circuits in one chip includes an A/D converter for converting an analog signal into a digital signal and a D/A converter for converting the digital signal into the analog signal in a section interfacing with outside of the LSI. When a burn-in test signal (digital signal) whose voltage waveform has a rectangular shape (digital waveform) is applied to the analog circuit, a state transition time when the signal transition of the signal occurs is short, which often allows only a part of the analog circuit which execute a sampling operation. Therefore, it is necessary to operate the analog circuit in a broader range by inputting a burn-in test signal (analog signal) whose voltage waveform continuously changes in a sinusoidal or triangular wave shape (analog waveform) from outside of the LSI in order to secure reliability of the burn-in test. Further, it is necessary to generate a desired DC voltage outside of the LSI and apply the DC voltage as the burn-in test signal with respect to an analog input terminal that requires the input of an arbitrary fixed DC voltage during the burn-in test.

Based on the foregoing reasons, in the burn-in test of the analog circuit, the burn-in test signal with the analog waveform outputted from an analog-waveform burn-in test signal generator installed in a burn-in test signal applying device and the burn-in test signal of the desired DC voltage waveform generated outside of the LSI are conventionally inputted to the LSI. Further, the analog waveform that is most suitable is set in accordance with the respective types and operation conditions of the analog circuit, and a burn-in board is developed so that an electrical stress can be efficiently applied to the analog circuit.

However, in such the burn-in test, it is caused to increase number of development steps in a burn-in test environment and a scale of a burn-in test circuit so that it makes difficult to reduce costs.

No. H11-326465 of the Japanese Patent Applications Laid-Open recites the conventional technology wherein the output of the D/A converter in the LSI is used for the burn-in test signal of the analog waveform, however, the technology is disadvantageous in terms of chip costs because the burn-in test circuit requires a large overhead.

### SUMMARY OF THE INVENTION

Therefore, a main object of the present invention is to enable to simplify a burn-in test and reduce costs necessary in the burn-in test by generating a burn-in test signal to an analog circuit simply.

In order to achieve the foregoing object, a burn-in test signal generating circuit according to the present invention is a burn-in test signal generating circuit for an analog circuit in LSI, comprising a burn-in test signal path provided in parallel with an ordinary signal path to the analog circuit, and a signal waveform converting circuit for converting a signal voltage waveform from a digital waveform into an analog waveform or a direct-current waveform that is provided in the burn-in test signal path, wherein the ordinary signal path is controlled to switch over to the burn-in test signal path in performing the burn-in test of the analog circuit.

According to the burn-in test signal generating circuit according to the present invention, the burn-in test signal whose voltage waveform is the digital waveform, that is, the digital signal, is applied from outside of the LSI, so that the burn-in test signal whose voltage waveform is the analog waveform can be automatically applied to the analog circuit as an electrical stress. Accordingly, as it becomes unnecessary to apply the burn-in test signal to the analog circuit in the LSI through the burn-in test signal applying device which is externally provided, it is possible to reduce the development steps in the burn-in test environment. Further, since the costs for the burn-in test are reduced, cost reduction of the LSI can be thereby achieved.

According to the burn-in test signal generating circuit according to the present invention, the burn-in test signal whose voltage waveform is the digital waveform is inputted to the burn-in test signal path, and the burn-in test signal whose voltage waveform is the direct-current waveform (DC voltage) is generated by controlling a frequency and a duty ratio of the voltage waveform of the inputted burn-in test signal. Accordingly, a desired DC voltage can be generated and applied as the burn-in test signal to a terminal also in the LSI that requires the application of an arbitrary constant voltage. As a result, any external component and burn-in test signal applying device, which were conventionally required in order to generate an arbitrary voltage outside the LSI, are no longer necessary, and the costs for the burn-in test can be thereby significantly reduced. The constitution is particularly effective for the burn-in test implemented at a wafer level where the number of external components on a burn-in test board is limited.

It is preferable that the signal waveform converting circuit consists of a charging/discharging circuit comprising a resistance element and a capacitance element. The charging/discharging circuit is configured in such a manner that the resistance element is serially connected to the burn-in test signal path and the capacitance element thereof is connected between an end of the burn-in test signal path on the analog-circuit side and a ground, wherein a resistance value of the resistance element and a capacitance value of the capacitance element are appropriately set so that the analog waveform can be adjusted.

It is desirable that the capacitance element is embedded in the LSI because the number of the components can be reduced.

A burn-in testing method according to the present invention is a method of implementing a burn-in test to an analog circuit in LSI, wherein a burn-in test signal path is provided in parallel with a ordinary signal path to the analog circuit, and a signal waveform converting circuit, that converts a signal voltage waveform from a digital waveform into an analog waveform, is provided in the burn-in test signal path, so that the ordinary signal path is controlled to switch over to the burn-in test signal path in the burn-in test of the analog circuit even as the burn-in test signal whose voltage waveform is the digital waveform is inputted to the burn-in test signal path, and then the voltage waveform of the inputted burn-in test signal is converted into the analog waveform by the signal waveform converting circuit and inputted to the analog circuit.

According to the burn-in testing method, the burn-in test signal whose voltage waveform is the digital waveform, that is, the digital signal, is applied from outside of the LSI, and thereby the burn-in test signal whose voltage waveform is the analog waveform can be automatically applied to the analog circuit as an electrical stress. Accordingly, since it becomes unnecessary to apply the burn-in test signal to the analog circuit in the LSI through the burn-in test signal applying device which is externally provided, it is possible to reduce the development steps in the burn-in test environment. Further, it becomes possible to reduce the costs for the burn-in test, and cost reduction of the LSI can be thereby achieved.

Another burn-in testing method according to the present invention is a method of implementing a burn-in test to an analog circuit in LSI, wherein a burn-in test signal path is provided in parallel with a ordinary signal path to the analog circuit and a signal waveform converting circuit for converting a signal voltage waveform from a digital waveform into an analog waveform is provided in the burn-in test signal path, so that the ordinary signal path is controlled to switch over to the burn-in test signal path in the burn-in test of the analog circuit even as the burn-in test signal having the digital waveform whose frequency of voltage and duty ratio are controlled is inputted to the burn-in test signal path, and then the voltage waveform of the inputted burn-in test signal is converted into a waveform of a direct-current voltage (DC voltage) by the signal waveform converting circuit in accordance with the control thereof and inputted to the analog circuit.

According to this burn-in testing method, a desired DC voltage can be generated and applied as the burn-in test signal to a terminal even in the LSI which requires the application of an arbitrary constant voltage. As a result, any external component and burn-in test signal applying device, which were conventionally required in order to generate an arbitrary voltage outside the LSI, are no longer necessary, and the costs for the burn-in test can be thereby significantly reduced. The constitution is particularly effective for the burn-in test implemented at a wafer level where the number of external components on a burn-in test board is limited.

In the present invention, a sufficient electrical stress can be applied to the analog circuit even in the case where the signal applied from the outside in the burn-in test is only the burn-in test signal (digital signal) whose voltage waveform is the digital waveform, and thereby it can facilitate the design of the burn-in test environment.

Further, the desired DC voltage can be generated through the control of the frequency and the duty of the externally applied signal which is the burn-in test signal having the digital waveform (digital waveform) even at the terminal of the LSI which requires the application of the arbitrary constant voltage. As a result, any external component and burn-in test signal applying device, which were conventionally required in order to generate an arbitrary voltage outside the LSI, are no longer necessary, and the costs for the burn-in test can be significantly reduced. The constitution is particularly effective for the burn-in test implemented at the wafer level where the number of external components on the burn-in test board is limited.

As described above, the burn-in test of the analog circuit in the LSI can be effectively and easily realized according to the present invention.

### BRIEF DESCRIPTION OF THE DRAWINGS

These and other objects as well as advantages of the invention will become clear by the following description of preferred embodiments of the invention. A number of benefits not recited in this specification will come to the attention of those skilled in the art upon the implementation of the present invention.

FIG. 1 shows an example of a burn-in test signal generating circuit according to a preferred embodiment 1 of the present invention.

FIGS. 2 shows an example of a waveform state in the burn-in test signal generating circuit shown in FIG. 1.

FIG. 3 shows an example of a burn-in test signal generating circuit according to a preferred embodiment 2 of the present invention.

FIG. 4 shows an example of a waveform state in the burn-in test signal generating circuit shown in FIG. 2.

### DETAILED DESCRIPTION OF THE INVENTION

Hereinafter, description will be given to preferred embodiments of a burn-in test signal generating circuit with respect to an analog circuit of a semiconductor integrated circuit and a burn-in testing method using the circuit according to the present invention, referring to the accompanied drawings.

### Preferred Embodiment 1

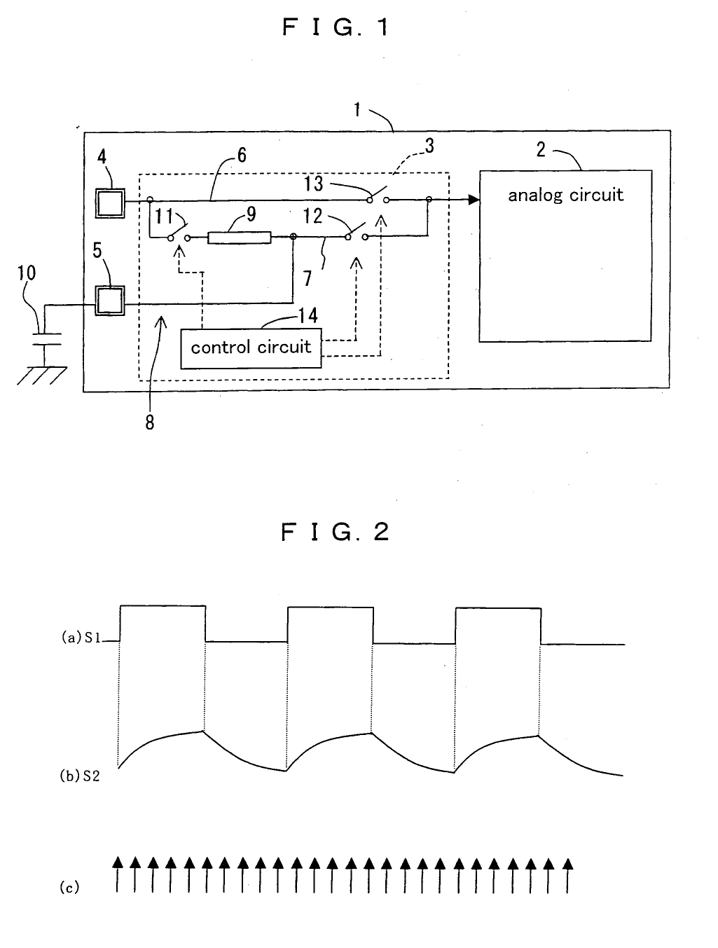

Below is shown a burn-in test signal generating circuit according to a preferred embodiment 1 of the present invention. FIG. 2 shows an example of a waveform in the burn-in test signal generating circuit. A semiconductor integrated circuit (LSI) 1 for implementing the burn-in test according the preferred embodiment 1 is provided in a combination with digital and analog circuits. FIG. 1 shows only an analog circuit 2 of the LSI 1. The burn-in test signal generating circuit 3 according to the preferred embodiment 1 is incorporated in the LSI 1. The LSI 1 comprises an analog input terminal 4 and an external capacitance connecting terminal 5.

An ordinary signal path 6 is provided between the analog input terminal 4 and the analog circuit 2, and a burn-in test signal path 7 is connected in parallel with the ordinary signal path 6. In the burn-in test signal path 7, a signal waveform converting circuit 8 for converting a burn-in test signal whose voltage waveform is a digital waveform (hereinafter, referred to as digital signal) into a burn-in test signal whose voltage waveform is an analog waveform (waveform having a triangular or sinusoidal waveform shape or the like) (hereinafter, referred to as analog signal) is provided. The signal waveform converting circuit 8 comprises, for example, a charging/discharging circuit consisting of a resistance element 9 and a capacitance element 10. In the burn-in test signal path 7, a first signal path selecting switch 11, the resistance element 9 and a second signal path selecting switch 12 are serially connected. A connecting point between the resistance element 9 and the second signal path selecting switch 12 is connected to an external capacitance connecting terminal 5. The capacitance element 10 is connected between the capacitance connecting terminal 5 and a ground part. A third signal path selecting switch 13 is connected to the ordinary signal path 6. The first, second and third signal path selecting switches 11, 12 and 13 consist of FET or the like, for example, as an analog switch, and the respective switches are controlled to turn on and off by a control circuit 14.

In the case where the first and second signal path selecting switches 11 and 12 are turned off and the third signal path selecting switch 13 is turned on by the control circuit 14, a signal inputted from the analog input terminal 4 is inputted to the analog circuit 2 as an ordinary signal via the ordinary signal path 6.

In the case where the first and second signal path selecting switches 11 and 12 are turned on and the third signal path selecting switch 13 is turned off by the control circuit 14, the digital signal inputted from the analog input terminal 4 is inputted to the analog circuit 2 via the burn-in test signal path 7. At the same time, the digital signal is charged/discharged by the charging/discharging circuit comprising the resistance element 9 and the capacitance element 10, and as a result the digital signal is converted into the analog signal.

An operation is described referring to a timing chart shown in FIG. 2. FIG. 2(a) shows a digital signal S1 applied to the analog signal terminal 4. FIG. 2(b) shows an analog signal S2 applied to the analog circuit 2. FIG. 2(c) shows sampling points of the analog circuit 2. These drawings show a waveform transition state when the digital signal is applied to the analog input terminal 4.

First, when a voltage level of the digital signal S1 changes from L (0=low value) to H (1=high value), the capacitance element 10 is charged via the resistance element 9. A time length for charging can be arbitrarily set in terms of a relationship between the resistance element 9 and the capacitance element 10, and a time length when a voltage level of the analog signal S2 applied to the analog circuit 2 shifts from L to H is longer than a time length when the voltage level of the digital signal S1 shifts from L to H.

Next, when the voltage level of the digital signal S1 changes from H to L, the capacitance element 10 is charged via the resistance element 9. A time length for discharging can be arbitrarily set in terms of the relationship between the resistance element 9 and the capacitance element 10, and a time length when the voltage level of the analog signal S2 applied to the analog circuit 2 shifts from H to L is longer than a time length when the voltage level of the digital signal S1 shifts from H to L. By performing the sampling operation of the analog circuit 2 during the transition period of the lengthened voltage level of the analog signal S2, a burn-in effect, that is equal to the case where the analog waveform such as sinusoidal wave or triangular wave is inputted from outside, can be obtained. Further, when the ordinary signal path 6 via the third signal path selecting switch 13 and the burn-in test signal path 7 via the first and second signal path selecting switches 11 and 12 are timely switched over to each other by the control circuit 14 during the burn-in test, the burn-in stress can be applied to all of the paths.

### Preferred Embodiment 2

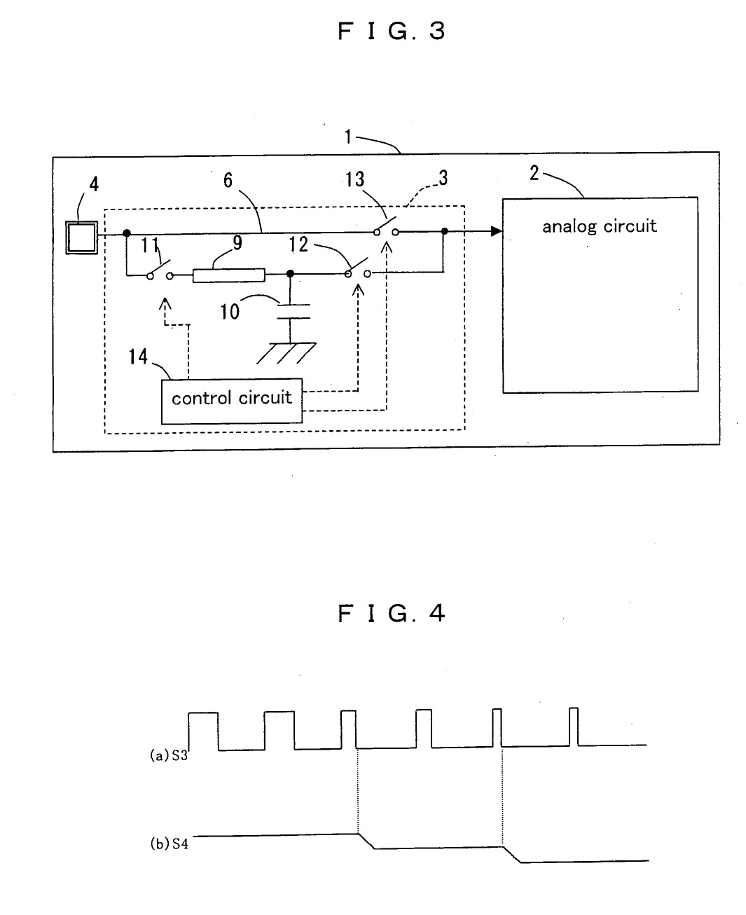

A burn-in test signal generating circuit and a burn-in testing method using the circuit according to a preferred embodiment 2 of the present invention are described referring to FIGS. 3 and 4. FIG. 3 shows an example of a constitution of the burn-in test signal generating circuit according to the preferred embodiment 2. FIG. 4 shows an example of a waveform state in the burn-in test signal generating circuit according to the preferred embodiment 2. In a burn-in test signal generating circuit 3 according to the preferred embodiment 2, the capacitance connecting terminal 5 recited in the preferred embodiment 1 is not provided, and the capacitance element 10 is incorporated in the LSI 1. Since the rest of the constitution, is similar to that of the preferred embodiment 1, it is not described again.

An operation according to the preferred embodiment 2 is described referring to FIG. 4. FIG. 4(a) shows a digital signal S3 applied to an analog input terminal 4. FIG. 4(b) shows a signal S4 inputted to an analog circuit 2. In the preferred embodiment 2, a frequency and a duty ratio of a digital waveform of the digital signal S3 are set in the digital signal S3, and the voltage waveform thereof is converted into a direct-current waveform signal (DC fixed voltage) through the charge/discharge of the resistance element 9 and the capacitance element 10. It constitutes a PWM (pulse width modulating) circuit in a simplified manner.

In the burn-in test wherein the analog circuit 2 is operated and the electrical stress is applied, particular accuracy is not necessary as far as the operation of the analog circuit 2 is within a tolerance range. Herewith, in the preferred embodiment 2, a burn-in effect, that is equal to the case where the DC voltage is generated outside and applied, can be realized in the present invention through the control of the digital signal S3.

Though the preferred embodiments of this invention have been described in detail, it will be understood that various modifications may be made therein, and it is intended to cover all such modifications in the appended claims as fall within the true spirit and scope of this invention.

What is claimed is:

1. A burn-in test signal generating circuit for an analog circuit in LSI, comprising:
a burn-in test signal path provided in parallel with an ordinary signal path to the analog circuit; and
a signal waveform converting circuit for converting a signal voltage waveform from a digital waveform into an analog waveform or a direct-current waveform in the burn-in test signal path, wherein the ordinary signal path is controlled to switch over to the burn-in test signal path in the burn-in test of the analog circuit.

2. The burn-in test signal generating circuit according to claim 1, wherein
the signal waveform converting circuit consists of a charging/discharging circuit comprising a resistance element and a capacitance element.

3. The burn-in test signal generating circuit according to claim 2, wherein
the capacitance element is provided in the LSI.

4. The burn-in test signal generating circuit according to claim 1, wherein
signal path selecting switches are provided on the ordinary-signal-path side and the burn-in-test-signal-path side respectively, and
the signal path selecting switch on the ordinary-signal-path side is switched over to OFF and the signal path selecting switch on the burn-in-test-signal-path side is switched over to ON in the burn-in test respectively.

5. The burn-in test signal generating circuit according to claim 2, wherein
a signal path selecting switch is provided on the ordinary-signal-path side an the burn-in-test-signal-path side respectively, and
the signal path selecting switch on the ordinary-signal-path side is switched over to OFF and the signal path selecting switch on the burn-in-test-signal-path side is switched over to ON in the burn-in test respectively.

6. The burn-in test signal generating circuit according to claim 3, wherein
a signal path selecting switch is provided on the ordinary-signal-path side an the burn-in-test-signal-path side respectively, and
the signal path selecting switch on the ordinary-signal-path side is switched over to OFF and the signal path selecting switch on the burn-in-test-signal-path side is switched over to ON in the burn-in test respectively.

7. A burn-in testing method for implementing a burn-in test to an analog circuit in LSI, comprising:
a burn-in test signal path provided in parallel with a ordinary signal path to the analog circuit; and
a signal waveform converting circuit for converting a signal voltage waveform from a digital waveform into an analog waveform in the burn-in test signal path, wherein
the ordinary signal path is controlled to switch over to the burn-in test signal path in the burn-in test of the analog circuit, the burn-in test signal whose voltage waveform is the digital waveform is inputted to the burn-in test signal path, and the voltage waveform of the inputted burn-in test signal is converted into the analog waveform by the signal waveform converting circuit and inputted to the analog circuit.

8. A burn-in testing method for implementing a burn-in test to an analog circuit in LSI, comprising:
a burn-in test signal path provided in parallel with a ordinary signal path with respect to the analog circuit; and
a signal waveform converting circuit for converting a signal voltage waveform from a digital waveform into an analog waveform in the burn-in test signal path, wherein
the ordinary signal path is controlled to switch over to the burn-in test signal path in the burn-in test of the analog circuit and the burn-in test signal having the digital waveform whose frequency and duty ratio are controlled is inputted to the burn-in test signal path, and then the voltage waveform of the inputted burn-in test signal is converted into a waveform of a direct-current voltage (DC voltage) by the signal waveform converting circuit in accordance with the control thereof and inputted to the analog circuit.
